(19) United States
(12) Patent Application Publication
(10) Pub. No.: US 2026/0164722 A1
(43) Pub. Date: Jun. 11, 2026

(54) TRANSISTOR AND DISPLAY DEVICE INCLUDING THE SAME

(71) Applicant: LG Display Co., Ltd., Seoul (KR)

(72) Inventors: Woo Seok JEONG, Paju-si (KR); Jeong Yeop LEE, Paju-si (KR); Jung Seok SEO, Paju-si (KR); Kyung Chul OK, Paju-si (KR); Jong Ho KIM, Paju-si (KR)

(73) Assignee: LG Display Co., Ltd., Seoul (KR)

(21) Appl. No.: 19/374,935

(22) Filed: Oct. 30, 2025

(30) Foreign Application Priority Data
Dec. 10, 2024 (KR) 10-2024-0183012

(51) Int. Cl. H10D 30/67; H10K 59/121

(52) U.S. Cl. CPC H10D 30/6757; H10D 30/6755; H10K 59/1213

(57) ABSTRACT

A transistor for a display device can include a first gate electrode, a first active layer overlapping with the first gate electrode, and a first source electrode and a first drain electrode contacting the first active layer. Also, the first active layer includes a first channel portion overlapping with the first gate electrode, a first conductive portion positioned at opposite sides of the first channel portion, the first conductive portion being doped with a first dopant and contacting the first source electrode and the first drain electrode, and a dual doping portion positioned between the first conductive portion and the first channel portion, the dual doping portion being doped with the first dopant and a second dopant different from the first dopant.

### CROSS REFERENCE TO RELATED APPLICATIONS

This application claims priority to Korean Patent Application No. 10-2024-0183012, filed in the Republic of Korea on Dec. 10, 2024, the entirety of which is hereby incorporated by reference into the present application as if fully set forth herein.

### BACKGROUND

### Field of the Invention

The present disclosure relates to a transistor and a display device including the same.

### Discussion of the Related Art

Display devices that display images such as TVs, monitors, smartphones, tablets, and laptops are being used in various ways and forms.

Display devices include a display panel including a plurality of light emitting elements or liquid crystals to display images and a transistor to control the operation of each of the light emitting elements or liquid crystals, to display a desired image through the light emitting elements or liquid crystals.

Display devices include a plurality of pixels including light emitting elements and thus include a plurality of driving and switching elements to drive and control the light emitting elements provided in the respective pixels. The driving and switching elements can include transistors.

Recently, various research and developments are being conducted to improve the performance and reliability of transistors.

Recently, research on small display panels is being actively conducted and smaller transistor elements that are more stable are desired to increase the pixels per inch (PPI) of small display panels.

### SUMMARY OF THE DISCLOSURE

Accordingly, the present disclosure is directed to a transistor and a display device including the same that substantially obviate one or more problems due to limitations and disadvantages of the related art.

An object of the present disclosure is to provide a transistor with improved reliability and a display device including the same.

Another object of the present disclosure is to provide a transistor structure that suppresses a phenomenon in which the threshold voltage Vth of a small transistor with a relatively small channel length is shifted negatively.

Another object of the present disclosure is to provide a structure that minimizes the length of the offset portion to maximize the channel length of a small transistor.

A further another object of the present disclosure is to provide a structure in which Environmental, Social, and Governance (ESG) goals are realized by improving the reliability of a transistor and a display device and reducing power consumption.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the disclosure, as embodied and broadly described herein, a transistor includes a first gate electrode, a first active layer overlapping the first gate electrode, and a first source electrode and a first drain electrode contacting the first active layer, in which the first active layer includes a first channel portion positioned at a part overlapping the first gate electrode, a first conductive portion positioned at both sides of the first channel portion, the first conductive portion being doped with a first dopant and contacting the first source electrode and the first drain electrode, and a dual doping portion positioned between the first conductive portion and the first channel portion, the dual doping portion being doped with a combination of the first dopant and a second dopant different from the first dopant.

A resistance of the dual doping portion can be higher than a resistance of the first conductive portion and can be lower than a resistance of the first channel portion. A carrier concentration in the dual doping portion can be lower than a carrier concentration in the first conductive portion and can be higher than a carrier concentration in the first channel portion.

A width of the dual doping portion can be smaller than a width of the first conductive portion.

A concentration of the first dopant and a concentration of the second dopant in the dual doping portion can be different from each other. For example, when the first dopant contains boron (B) and the second dopant contains fluorine (F), the concentration of the fluorine in the dual doping portion can be less than the concentration of the boron.

The transistor can further include a first offset portion positioned between the dual doping portion and the first channel portion and having a carrier concentration increasing from the first channel portion to the dual doping portion.

A width of the dual doping portion can be greater than a width of the first offset portion and can be smaller than a width of the first conductive portion.

The first active layer can include an oxide semiconductor.

In another aspect of the present disclosure, a display device includes a substrate, a switching transistor disposed on the substrate, the switching transistor including a first gate electrode, a first source electrode, a first drain electrode, and a first active layer, and a driving transistor disposed on the substrate and spaced apart from the switching transistor, the driving transistor including a second gate electrode, a second source electrode, a second drain electrode, and a second active layer, in which the first active layer includes a first channel portion positioned at a part overlapping the first gate electrode, a first conductive portion positioned at both sides of the first channel portion, the first conductive portion being doped with a first dopant and contacting the first source electrode and the first drain electrode, and a dual doping portion positioned between the first conductive portion and the first channel portion, the dual doping portion being doped with a combination of the first dopant and a second dopant different from the first dopant, in which the second active layer includes a second channel portion positioned at a part overlapping the second gate electrode, a second conductive portion positioned at both sides of the second channel portion and doped with a first dopant, the second conductive portion contacting the second source electrode and the second drain electrode, and a second offset portion positioned between the second channel portion and the second conductive portion, the second offset portion being doped with the first dopant and having a resistance that gradually changes.

The second active layer can do not include the dual doping portion doped with the first and second dopants together.

A resistance of the dual doping portion can be higher than a resistance of the first conductive portion and can be lower than a resistance of the first channel portion. A carrier concentration in the dual doping portion can be lower than a carrier concentration in the first conductive portion and can be higher than a carrier concentration in the first channel portion.

A width of the dual doping portion can be smaller than a width of the first conductive portion.

A concentration of the first dopant and a concentration of the second dopant in the dual doping portion can be different from each other. For example, when the first dopant contains boron (B) and the second dopant contains fluorine (F), the concentration of the fluorine in the dual doping portion can be less than the concentration of the boron.

The display device can further include a first offset portion positioned between the dual doping portion and the first channel portion and having a carrier concentration increasing from the first channel portion to the dual doping portion.

The first and second active layers can include an oxide semiconductor.

It is to be understood that both the foregoing general description and the following detailed description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 illustrates an example of a display device according to an embodiment of the present disclosure;

FIG. 2, including parts (a) and (b), illustrates an example of an equivalent circuit for a subpixel SP applicable to the display device according to an embodiment of the present disclosure;

FIG. 3 illustrates a switching transistor shown in FIG. 2 according to an embodiment of the present disclosure;

FIG. 4 illustrates the switching transistor shown in FIG. 2 according to another embodiment of the present disclosure;

FIG. 5, including parts (a) and (b), illustrates a carrier concentration and resistance depending on an area of the switching transistor shown in FIG. 4 according to an embodiment of the present disclosure;

FIG. 6, including parts (a)-(d), illustrates an example of a method of manufacturing the switching transistor according to an embodiment of the present disclosure;

FIG. 7, including parts (a) and (b), illustrates the effect of the dual doping portion in the switching transistor according to an embodiment of the present disclosure;

FIG. 8 illustrates comparison between a driving transistor applicable to the display device and a switching transistor according to an embodiment of the present disclosure; and

FIG. 9 illustrates an example in which the switching transistor and the driving transistor are applied to the display device according to an embodiment of the present disclosure.

### DETAILED DESCRIPTION OF THE EMBODIMENTS

Reference will now be made in detail to embodiments of the present disclosure, examples of which are illustrated in the accompanying drawings.

Like reference numbers refer to like components throughout the description of the figures. The thickness, ratio, size, and the like of components shown in the drawings to illustrate various embodiments of the present disclosure are exaggerated for better illustration. The scale of the components shown in the drawings is different from the actual scale for better illustration and is therefore not limited to the scale shown in the drawings.

It will be understood that, when an element (or a region, layer, part or the like) is referred to as being “on,” “connected to” or “bonded to” another element, it can be directly on, connected to or bound to the other element, or an intervening element can also be present therebetween.

The term “and/or” includes all of one or more combinations that can be defined by the associated components.

In describing the variety of embodiments of the present disclosure, terms such as “first” and “second” can be used to describe a variety of components, but these terms only aim to distinguish the same or similar components from one another. Accordingly, throughout the disclosure, a “first” component can be referred to as a “second” component within the technical concept of the present disclosure. Similarly, a “second” component can be referred to as a “first” component within the technical concept of the present disclosure. Singular forms are intended to include plural forms as well, unless the context clearly indicates otherwise.

The terms such as “below,” “beneath,” “above” and “upper” are used to describe the relationships between components shown in the drawings. The terms are relative concepts and are described based on the directions indicated in the drawings. For example, unless “immediately” or “directly” is used, one or more other components can be located between two components. The spatially relative terms such as “below,” “beneath,” “lower,” “above” and “upper” can be used to easily describe the relationships between one element or component and another element or component as depicted in the drawings. Thus, for example, “below” and “lower” with respect to a first component can be in the opposite direction to “above” and “upper” with respect to the first component.

Spatially relative terms should be understood to include different orientations of elements when used or operated in addition to the orientation depicted in the drawings. For example, when elements depicted in the drawings are flipped over, an element described as “below” or “beneath” another element can be disposed “above” the other element. Thus, the term “below” can include both above and below.

It will be further understood that the terms “comprises” and/or “has,” when used herein, specify the presence of stated features, integers, steps, operations, elements, components or combinations thereof, but do not preclude the presence or addition of one or more other features, integers, steps, operations, elements, components, or combinations thereof.

Features of various embodiments of the present disclosure can be partially or completely integrated or combined with each other, and can be variously interoperated with each other and driven technically. The embodiments of the present disclosure can be carried out independently from each other, or can be carried out together in an interrelated manner. Also, the term “can” used herein includes all meanings and definitions of the term “may.”

Hereinafter, the display device according to embodiments of the present disclosure will be described with reference to the attached drawings and embodiments as follows.

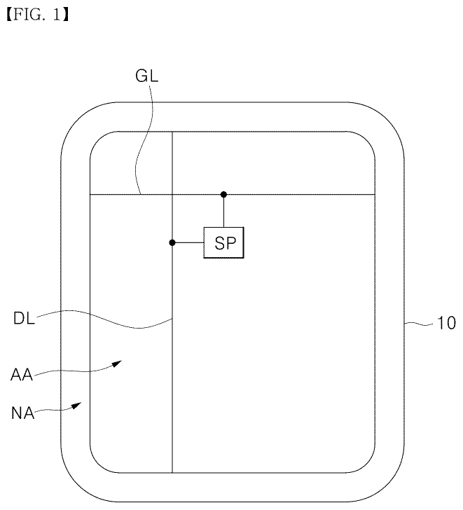

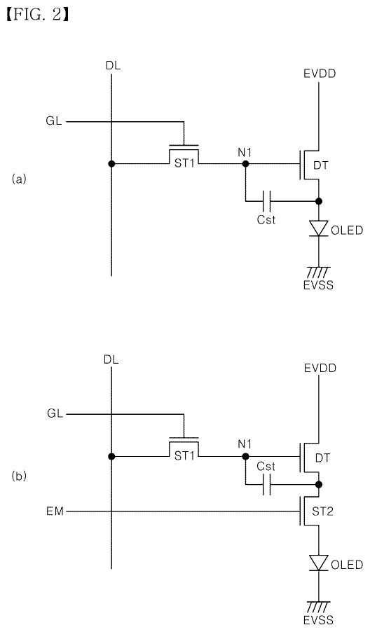

FIG. 1 illustrates an example of a display device applicable to the present disclosure, and FIG. 2, including parts (a) and (b), illustrates an example of an equivalent circuit for a subpixel SP applicable to the display device of the present disclosure.

Referring to FIGS. 1 and 2, the display device according to an example of the present disclosure includes a display panel 10 and the display panel 10 can include an active area AA and a non-active area NA.

The active area AA can be an area for displaying an image. A plurality of subpixels SP can be disposed in the active area AA of the display panel 10 and an image can be displayed using the subpixels SP. The area where the subpixels SP are disposed can correspond to an active area AA and an area other than the active area AA can correspond to a non-active area NA.

The non-active area NA can be disposed in an edge area surrounding the active area AA where an image is displayed. At least one driving unit to drive a plurality of subpixels SP can be disposed in the non-active area NA. The driving unit can be a gate in-panel (GIP).

Various additional elements can be further disposed in the non-active area NA to drive the subpixels SP in the active area AA.

At least one subpixel SP can include, for example, a circuit including a first switching transistor ST1, a driving transistor DT, a capacitor Cst, or a light emitting element OLED, as shown in part (a) or part (b) of FIG. 2.

A first electrode (e.g., a drain electrode) of the first switching transistor ST1 can be electrically connected to a data line DL, a second electrode (e.g., a source electrode) can be electrically connected to a first node N1, and a gate electrode of the first switching transistor ST1 can be electrically connected to a gate line GL. The first switching transistor ST1 can transmit a data signal supplied through the data line DL to the first node N1 in response to a scan signal supplied through the gate line GL.

The capacitor Cst can be electrically connected to the first node N1 and can be charged with a voltage applied to the first node N1.

The first electrode (e.g., the drain electrode) of the driving transistor DT can receive a high-potential driving voltage EVDD and the second electrode (e.g., the source electrode) can be electrically connected to the first electrode (e.g., the anode) of the light emitting element OLED. The driving transistor DT can generate driving current flowing to the light emitting element OLED in response to the voltage applied to the gate electrode.

The active layer of the first switching transistor ST1 and/or the driving transistor DT can contain oxide such as indium-gallium-zinc-oxide (IGZO), but is not limited thereto.

The light emitting element OLED can output light corresponding to the driving current. The light emitting element OLED can output light of one of the colors of red (R), green (G), blue (B), and white (W).

The light emitting element OLED can include an anode, a light emitting layer disposed on the anode, and a cathode supplying a common voltage.

A driving current generated by the driving transistor can be applied to the anode of the light emitting element and a low-potential driving voltage (EVSS) can be applied to the cathode of the light emitting element.

The light emitting layer can be realized to emit light of the same color for each pixel, such as white light, or can be realized to emit different colors for the respective subpixels SP, such as red (R), green G, and blue (B) light.

The light emitting element OLED can be a top-emission diode or a bottom-emission diode.

FIG. 2, part (a) illustrates an example in which the driving transistor DT is directly connected to the light emitting element OLED, but the present disclosure is not limited thereto. As shown in FIG. 2, part (b), the driving transistor DT can be connected to the light emitting element OLED via a second switching transistor ST2.

Specifically, as shown in FIG. 2, part (b), the second switching transistor ST2 can be disposed between the driving transistor DT and the light emitting element OLED, a first electrode of the second switching transistor ST2 can be connected to the driving transistor DT, and a second electrode of the second switching transistor ST2 can be electrically connected to the light emitting element OLED. In response to a light emitting signal applied to the gate electrode of the driving transistor DT, on/off of the driving current applied from the driving transistor DT to the light emitting element OLED can be controlled.

In addition, a compensation circuit for compensating for a threshold voltage Vth of the driving transistor DT, which is a driving transistor, can be further provided within the subpixel SP. The compensation circuit can include at least one transistor connected to the driving transistor DT and can be provided in the subpixel SP.

Depending on the configuration mode, the compensation circuit can have various configurations, such as 3T1C including three transistors and one capacitor Cst within the subpixel SP, or 4T2C including four transistors and two capacitors Cst, or 5T2C, 6T1C, 6T2C, 7T1C, 7T2C, or the like.

Meanwhile, each transistor constituting the circuit of the subpixel as shown in FIG. 2 can be stably driven when the channel region has a sufficient length, and as a result, the reliability of the transistor and the display device can be improved and the power consumption can be reduced.

In FIG. 2, switching transistors such as ST1 and ST2 can be formed with a relatively short channel length in order to increase the circuit directivity due to the narrow space compared to the driving transistor. However, when the channel length is shortened below a predetermined level, a problem can occur in which the channel becomes conductive or the threshold voltage Vth shifts negatively (−). For example, a negative shift in the threshold voltage Vth can present a significant problem, particularly for small transistors with relatively short channel lengths. This shift in the threshold voltage Vth can lead to the channel of the transistor becoming prematurely conductive or even conductive below its intended threshold (or stuck on), which can impair the reliability and performance of the transistor and the display device. For example, this negative Vth shift can lead to increased power consumption in the display device (e.g., increased leakage current).

In order to solve this problem, an embodiment of the present disclosure can have a dual doping portion doped with a combination of first and second dopants in the active layer of the transistor, thereby suppressing the channel length from being shortened below a predetermined level. The dual doping portion can be mainly applied to the switching transistor, but embodiments of the present disclosure are not limited thereto. In some situations, the dual doping portion can be applied to the driving transistor and can also be applied to the transistor included in the GIP driving circuit disposed in the non-active area (NA).

Hereinafter, an example of a structure of a switching transistor including the dual doping portion according to an embodiment of the present disclosure will be described.

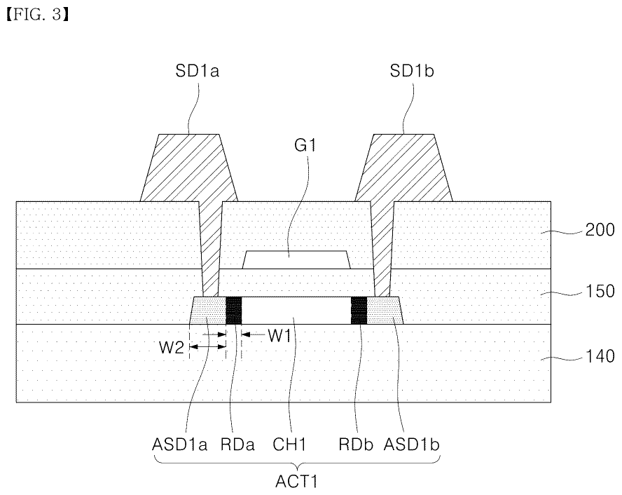

FIG. 3 illustrates a first embodiment of the switching transistor shown in FIG. 2.

As shown in FIG. 3, the switching transistor according to the first embodiment of the present disclosure can include a first gate electrode G1, a first active layer ACT1, a first source electrode SD1a, and a first drain electrode SD1b, and can include a buffer layer 140 under the first active layer ACT1, a gate insulating film 150 between the first active layer ACT1 and the first gate electrode G1, and an interlayer insulating film 200 on the gate insulating film 150.

Also, the substrate can be disposed under the buffer layer 140. The following description will be provided on the assumption that the substrate is disposed under the buffer layer 140.

The first gate electrode G1 can overlap with the first active layer ACT1 and can be spaced apart from the first active layer ACT1. The first gate electrode G1 can be controlled to form a channel in the channel region CH of the active layer through an applied voltage.

The first gate electrode G1 can include a conductive material, for example, a metal such as aluminum (Al), chromium (Cr), copper (Cu), titanium (Ti), molybdenum (Mo), or tungsten (W).

The first active layer ACT1 can be disposed on the buffer layer 140 and can be disposed in a part overlapping with the first gate electrode G1.

The first active layer ACT1 can include an oxide semiconductor. The oxide semiconductor material contained in the first active layer ACT1 can for example include at least one of an IZO (InZnO)-based, an IGO (InGaO)-based, an ITO (InSnO)-based, an IGZO (InGaZnO)-based, an IGZTO (InGaZnSnO)-based, a GZTO (GaZnSnO)-based, a GZO (GaZnO)-based, an ITZO (InSnZnO)-based, or a FIZO (FeInZnO)-based oxide semiconductor material.

The first active layer ACT1 can include a first channel portion CH1, first conductive portions ASD1a and ASD1b, and dual doping portions RDa and RDb.

The first channel portion CH1 can be positioned at a portion of the first active layer ACT1 that overlaps with the first gate electrode G1, and can be a region not doped with first and second dopants. For example, the first channel portion CH1 may not include the first and second dopants. The first channel portion CH1 can form a channel through which carriers can move within the first active layer ACT1 depending on the voltage applied to the first gate electrode G1.

The first conductive portions ASD1a and ASD1b can be positioned at both sides of the first channel portion CH1, can be doped with the first dopant, and can contact a first source electrode SD1a and a first drain electrode SD1b. For example, according to an embodiment, the first conductive portions ASD1a and ASD1b may not include the second dopant.

The first conductive portions ASD1a and ASD1b can be regions where the first active layer ACT1 is conductive, can have a higher carrier concentration than the first channel portion CH1, and can have higher electrical conductivity and lower resistance than the first channel portion CH1. One of the first conductive portions ASD1a and ASD1b can correspond to a first source region ASD1a and the other can correspond to a second drain region ASD1b.

The dual doping portions RDa and RDb can be positioned between the first conductive portions ASD1a and ASD1b, and the first channel portion CH1, and can be doped with a combination of the first dopant and the second dopant. The second dopant is different from the first dopant. The dual doping portions RDa and RDb can suppress a phenomenon in which the threshold voltage Vth of the transistor shifts negatively (−) and suppress the occurrence of an offset portion, thereby maximizing the width of the first channel portion CH1 of the transistor. For example, the dual doping portions (RDa and RDb) are areas within the transistor located between the conductive parts (ASD1a and ASD1b) and the central channel (CH1). These portions can be treated with two different dopants to prevent the transistor's “turn-on” voltage (Vth) from shifting negatively and suppress undesirable “offset portions,” in order to maximize the width or length of the transistor's channel for improved performance and saved space (e.g., providing a smaller footprint).

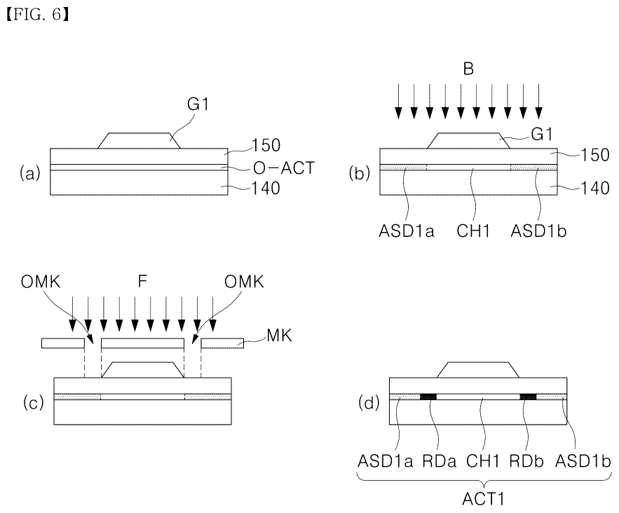

The first dopant can increase the carrier concentration in the first conductive portions ASD1a and ASD1b and the dual doping portions RDa and RDb, thereby lowering the resistance of the first conductive portions ASD1a and ASD1b, and the second dopant can suppress the diffusion of Vo (oxygen vacancy) within the dual doping portions RDa and RDb during the subsequent heat treatment process and can reduce the carrier concentration while forming a chemical bond with a metal material. Accordingly, the dual doping portions RDa and RDb can suppress the occurrence of an offset portion. For example, the first dopant can increase carrier concentration in the conductive and dual doping portions which lowers resistance in the conductive areas, while the second dopant in the dual doping portions can suppresses oxygen vacancy diffusion and reduces carrier concentration by forming chemical bonds with metal materials. This combined action of the dual doping portions can effectively prevent the formation of undesired offset portions. The effects of the dual doping portions RDa and RDb will be described in more detail later with reference to FIG. 6.

The dual doping portions RDa and RDb are positioned between the first conductive portions ASD1a and ASD1b, and the first channel portion CH1, and most of the dual doping portions RDa and RDb can be positioned outside of the first gate electrode G1. However, the present disclosure is not limited to the dual doping portions RDa and RDb being positioned only on the outside of the first gate electrode G1, and some areas of the dual doping portions RDa and RDb can overlap with the first gate electrode G1 due to process conditions or process errors.

The resistance of the dual doping portions RDa and RDb can be higher than the resistance of the first conductive portions ASD1a and ASD1b, and lower than the resistance of the first channel portion CH1 (e.g., resistances of ASD1a <RDa <CH1, and resistances of ASD1b<RDb<CH1). For example, the first dopant can reduce the resistance of the first active layer ACT1, and the second dopant can increase the resistance of the first active layer ACT1. Therefore, the dual doping portions RDa and RDb doped with a combination of the first dopant and the second dopant can have a higher resistance than the first conductive portions ASD1a and ASD1b doped with just the first dopant and not including the second dopant.

The width W1 of the dual doping portions RDa and RDb can be smaller than the width W2 of the first conductive portions ASD1a and ASD1b (e.g., W2>W1). Also, according to a reference point, the width W1 can also be referred to as a first length L1, and the width W2 can also be referred to as a second length L2, but embodiments are not limited thereto. The first conductive portions ASD1a and ASD1b can have a width W2 greater than the width W1 of the dual doping portions RDa and RDb in order to sufficiently secure an area where the first source electrode SD1a and the first drain electrode SD1b contact, and the dual doping portions RDa and RDb can have a width W1 within a range that can suppress the formation of an offset portion.

The concentration of the first dopant and the concentration of the second dopant in the dual doping portions RDa and RDb can be different from each other. For example, when the first dopant can include boron (B) and the second dopant can contain fluorine (F), the concentration of the second dopant, fluorine (F), in the dual doping portions RDa and RDb can be less than the concentration of the first dopant, boron (B).

Specifically, when the transistor has dual doping portions RDa and RDb doped with both boron and fluorine, as shown in FIG. 3, the phenomenon in which the threshold voltage Vth of the transistor shifts negatively can be suppressed through the dual doping portions RDa and RDb. In addition, as the doping concentration of fluorine increases, the ability of suppressing the threshold voltage Vth to shift negatively may be increased. In other words, as more fluorine is added, the transistor can become better a preventing its “turn-on” voltage (e.g., threshold voltage Vth) from shifting in an undesirable negative direction.

However, when the doping concentration of fluorine (F) is excessively greater than that of boron (B), the gate voltage (Vg)-drain current (Id) curve of the transistor is distorted and the on-current (Ion), which is the current when the transistor is turned on, deteriorates, thus making it difficult for the transistor to perform stable operation. according to the present disclosure, in consideration of this, it is possible to adjust the concentration of fluorine (F) to be less than that of boron (B). In other words, if the amount of fluorine (F) added is excessively high compared to boron (B), the electrical behavior of the transistor can become unpredictable, and the maximum current it can pass when on (e.g., its on-current) weakens, making stable operation difficult.

For example, the doping concentration of boron to the doping concentration of fluorine can be 1:0.15 to 1:0.35, and the doping concentration of fluorine in the dual doping portions RDa and RDb can be greater than 0 at % (atomic weight %) and less than 5 to 10 at % with respect to the total atomic weight of the dual doping portions RDa and RDb.

Each of the first source electrode SD1a and the first drain electrode SD1b can be electrically connected to the first conductive portion ASD1a or ASD1b. The first source electrode SD1a can contact the first source region ASD1a and the first drain electrode SD1b can contact the first drain region ASD1b.

For example, when the transistor of FIG. 3 is the first switching transistor ST1 of FIG. 2, one of the first source electrode SD1a and the first drain electrode SD1b can be electrically connected to the data line DL and the other can be connected to the first node N1. Alternatively, when the transistor of FIG. 3 is the second switching transistor ST2 of FIG. 2, one of the first source electrode SD1a and the first drain electrode SD1b can be electrically connected to the driving transistor DT and the other electrode can be electrically connected to the light emitting element OLED.

The buffer layer 140 can be disposed on the substrate and can include an inorganic insulating material such as silicon oxide (SiO) or silicon nitride (SiN). The buffer layer 140 can insulate the metal layer disposed between the buffer layer 140 and the substrate from the first active layer ACT1.

The gate insulating film 150 can be disposed between the first gate electrode G1 and the first active layer ACT1 and can insulate the first gate electrode G1 from the first active layer ACT1. The gate insulating film 150 can include at least one of silicon oxide (SiOx), silicon nitride (SiNx) or silicon oxynitride (SiOxNy). For example, silicon oxide (SiOx) can include silicon dioxide (SiO₂).

The interlayer insulating film 200 can be disposed on the gate insulating film 150 while covering the first gate electrode G1, and can extend along the extension direction of the gate insulating film 150. The interlayer insulating film 200 can include an insulating material such as silicon oxide (SiOx), silicon nitride (SiNx), or silicon oxynitride (SiOxNy). The first source electrode SD1a and the first drain electrode SD1b can be disposed on the interlayer insulating film 200 and can penetrate the interlayer insulating film 200 and the gate insulating film 150 to contact the first source region ASD1a and the first drain region ASD1b, respectively.

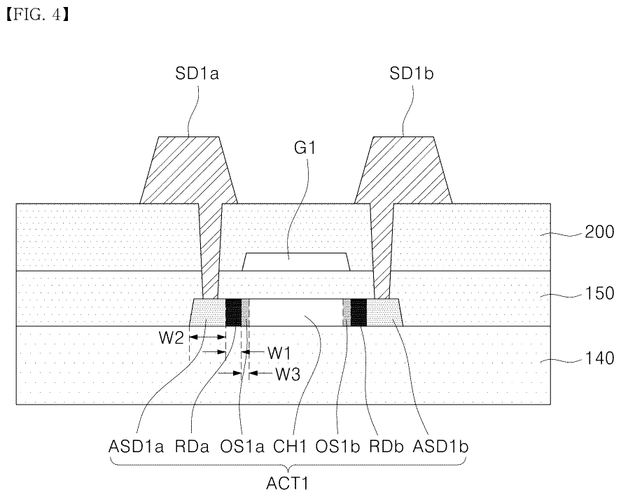

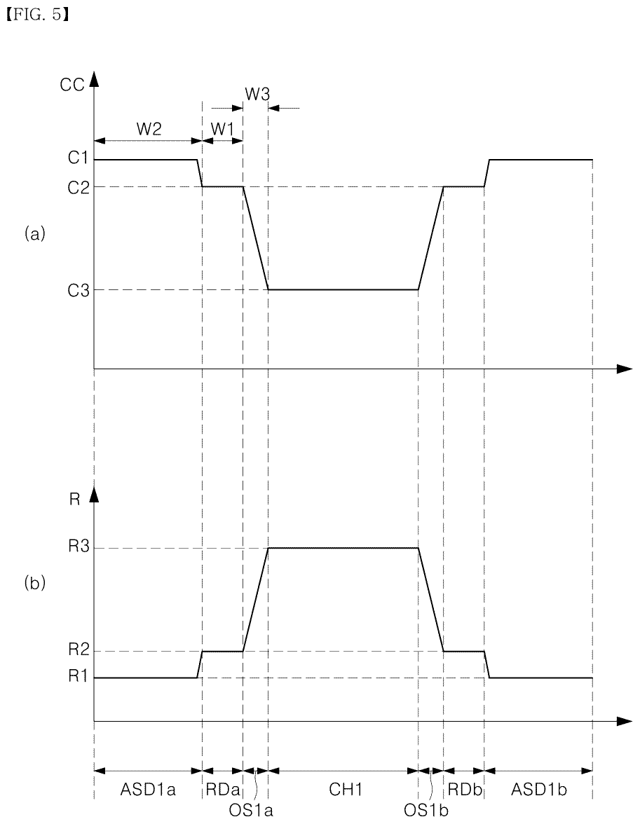

FIG. 4 illustrates a second embodiment of the switching transistor shown in FIG. 2, and FIG. 5 illustrates carrier concentration and resistance depending on the region of the switching transistor shown in FIG. 4. Part (a) of FIG. 5 is a graph showing the carrier concentration CC depending on each region of the transistor, and part (b) of FIG. 5 is a graph showing the resistance R depending on each region of the transistor.

Hereinafter, the following description with reference to FIG. 4 will focus on the difference from the content with reference to FIG. 3.

As shown in FIG. 4, the switching transistor according to the second embodiment of the present disclosure can include a first gate electrode G1, a first active layer ACT1, a first source electrode SD1a, and a first drain electrode SD1b, and can include a buffer layer 140 under the first active layer ACT1, a gate insulating film 150 between the first active layer ACT1 and the first gate layer, and an interlayer insulating film 200 on the gate insulating film 150.

The first active layer ACT1 can include a first channel portion CH1, first conductive portions ASD1a and ASD1b, and dual doping portions RDa and RDb, and can further include first offset portions OS1a and OS1b positioned between the dual doping portions RDa and RDb, and the first channel portion CH1.

The first offset portions OS1a and OS1b can have a carrier concentration that increases from the first channel portion CH1 to the dual doping portions RDa and RDb. For example, the first offset portions OS1a and OS1b can include a first region OS1a positioned between the first channel portion CH1 and the source region ASD1a, and a second region OS1b positioned between the first channel portion CH1 and the drain region ASD1b. For example, the offset portions (OS1a and OS1b) are regions where the amount of electrical carriers increases and the resistance decreases, as a distance away from the channel CH1 towards the dual doping portions increases.

As shown in the second embodiment, when the switching transistor has the first offset portions OS1a and OS1b, the width W1 of the dual doping portions RDa and RDb can be greater than the width W3 of the first offset portions OS1a and OS1b and can be less than the width W2 of the first conductive portions ASD1a and ASD1b. Also, according to an example, depending on reference point, the first, second and third widths W1, W2 and W3 can be referred to as first, second and third lengths L1, L2 and L3, but embodiments are not limited thereto.

The first offset portions OS1a and OS1b may be or may not be generated depending on the concentration of the second dopant, fluorine (F), doped into the dual doping portions RDa and RDb, the temperature of the subsequent heat treatment process, and the heat treatment time.

That is, when the concentration of the second dopant, fluorine (F), is high, the temperature of the subsequent heat treatment process can be relatively low, or the heat treatment time can be relatively short, the first offset portions OS1a and OS1b may not be generated, as shown in FIG. 3, and when the concentration of the second dopant, fluorine (F), is low, the temperature of the subsequent heat treatment process can be relatively high, or the heat treatment time can be relatively long, the first offset portions OS1a and OS1b can be generated, as shown in FIG. 4. However, as shown in FIG. 4, although the transistor is provided with the first offset portions OS1a and OS1b, the width W3 of the first offset portions OS1a and OS1b can be minimized due to the dual doping portions RDa and RDb (e.g., W3<W1<W2).

The carrier concentration CC and resistance R depending on each region of the transistor as shown in FIG. 4 are shown in FIG. 5.

As shown in part (a) of FIG. 5, the carrier concentration C3 of the first channel portion CH1 can be lower than the carrier concentration C1 of the first conductive portions ASD1a and ASD1b. The carrier concentration C2 of the dual doping portions RDa and RDb can be higher than the carrier concentration C3 of the first channel portion CH1 and can be less than the carrier concentration C1 of the first conductive portions ASD1a and ASD1b (e.g., C3<C2<C1). The carrier concentration of the first offset portions OS1a and OS1b can increase from the first channel portion CH1 to the dual doping portions RDa and RDb.

Accordingly, the resistance R3 of the first channel portion CH1 can be greater than the resistance R1 of the first conductive portions ASD1a and ASD1b. The resistance R2 of the dual doping portions RDa and RDb can be lower than the resistance R3 of the first channel portion CH1 and can be higher than the resistance R1 of the first conductive portions ASD1a and ASD1b (e.g., R3>R2>R1). The resistance of the first offset portions OS1a and OS1b can decrease from the first channel portion CH1 to the dual doping portions RDa and RDb.

FIG. 6 illustrates an example of a method of manufacturing the switching transistor of the present disclosure.

In order to manufacture the switching transistor of FIGS. 3 and 4, first, as shown in part (a) of FIG. 6, a buffer layer 140, an oxide semiconductor layer O-ACT, a gate insulating film 150, and a first gate electrode G1 can be sequentially formed on a substrate.

The oxide semiconductor layer O-ACT can include at least one of an IZO (InZnO)-based, an IGO (InGaO)-based, an ITO (InSnO)-based, an IGZO (InGaZnO)-based, an IGZTO an (InGaZnSnO)-based, a GZTO (GaZnSnO)-based, a GZO (GaZnO)-based, an ITZO (InSnZnO)-based, or a FIZO (FeInZnO)-based oxide semiconductor material.

Then, as shown in part (b) of FIG. 6, the oxide semiconductor layer O-ACT can be doped with the first dopant, boron (B), using the first gate electrode G1 as a mask. Accordingly, the portion overlapping the first gate electrode G1 in the oxide semiconductor layer O-ACT can be not doped with boron (B) and can be formed as a first channel portion CH1, and the portion not overlapping the first gate electrode G1 can be doped with boron (B) and can be formed as first conductive portions ASD1a and ASD1b.

Then, as shown in part (c) of FIG. 6, a mask MK having an opening OMK is disposed on the upper portion of the first gate electrode G1 and the oxide semiconductor layer O-ACT can be doped with fluorine (F), which is a second dopant. A part of the first conductive portions ASD1a and ASD1b exposed through the opening OMK of the mask MK can be further doped with fluorine (F). For example, the first dopant (B) can be applied across a larger area of the oxide semiconductor layer O-ACT than the second dopant (F).

The opening OMK of the mask MK can be disposed outside of the first gate electrode G1. For example, the opening OMK of the mask MK can be aligned with the end of the first gate electrode G1. The opening OMK of the mask MK can overlap with the first conductive portions ASD1a and ASD1b. The width of the opening OMK of the mask MK can be less than the width W2 of the first conductive portions ASD1a and ASD1b.

Accordingly, fluorine (F) can be doped with a part of the first conductive portions ASD1a and ASD1b overlapping with the opening OMK of the mask MK in the oxide semiconductor layer O-ACT. Therefore, the portion overlapping the opening OMK of the mask MK in the oxide semiconductor layer O-ACT can be formed as dual doping portions RDa and RDb by doping with the first dopant, boron (B) in combination with a second dopant, fluorine (F).

Accordingly, as shown in part (d) of FIG. 6, the oxide semiconductor layer O-ACT can be formed as a first active layer ACT1 including a first channel portion CH1, first conductive portions ASD1a and ASD1b, and dual doping portions RDa and RDb.

Then, an interlayer insulating film 200 can be deposited such that it covers the first gate electrode G1 and can then be heat-treated to complete a subsequent heat treatment process.

In this situation, depending on the concentration of fluorine (F) doped in the dual doping portions RDa and RDb, and the temperature and heat treatment time of the subsequent heat treatment process, the transistor not provided with the first offset portions OS1a and OS1b shown in FIG. 3 can be formed, or the transistor provided with the first offset portions OS1a and OS1b shown in FIG. 4 can be formed.

For example, when the concentration of doped fluorine (F) is high, the temperature of the subsequent heat treatment process is relatively low, or the heat treatment time is relatively short, the transistor provided with dual doping portions RDa and RDb, while not providing with the first offset portions OS1a and OS1b as shown in FIG. 3 can be formed. Alternatively, when the concentration of doped fluorine (F) is low, the temperature of the subsequent heat treatment process is relatively high, or the heat treatment time is relatively long, a transistor including the first offset portions OS1a and OS1b contacting the dual doping portions RDa and RDb as shown in FIG. 4 can be formed.

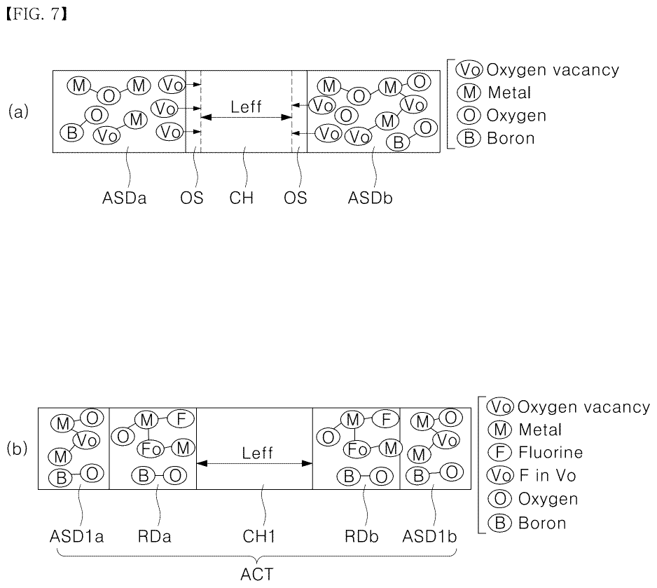

FIG. 7 illustrates the effect of the dual doping portion in the switching transistor according to an embodiment of the present disclosure.

Part (a) of FIG. 7 illustrates chemical bonding within an active layer when a subsequent heat treatment process is performed in a state where a conductive portion is formed by doping with boron (B) and doping with fluorine (F) is not performed in the transistor not provided with dual doping portions RDa and RDb.

Part (b) of FIG. 7 illustrates chemical bonding within an active layer when a subsequent heat treatment process is performed in a state where the dual doping portions RDa and RDb is doped with a combination of boron (B) and fluorine (F) in the transistor provided with dual doping portions RDa and RDb.

As shown in part (a) of FIG. 7, when the region where the conductive portions ASDa and ASDb are to be formed in the oxide semiconductor layer O-ACT is doped with only boron (B), boron (B) can break a metal-oxygen bond (M—O) contained in the conductive portions ASDa and ASDb to form a Vo (oxygen vacancy) and a metal (M). The metal (M) element can be, for example, a material such as indium (In), tin (Sn), or zinc (Zn) contained in the oxide semiconductor layer O-ACT.

Then, boron (B) and the metal (M) contained in the conductive portion ASDa or ASDb during the subsequent heat treatment process can be bonded to oxygen (O) to form a boron-oxygen bond (B—O) or a metal-oxygen bond (M—O), and some of the metal (M) can be bonded to the Vo to form a metal-Vo bond (M—Vo). Then, the residual Vo can provide electrons to form conductive portions ASDa and ASDb.

However, during the subsequent heat treatment process, as Vo adjacent to the channel CH in the conductive portions ASDa and ASDb diffuses toward the channel CH, an offset region OS can be formed in a part of the channel CH that contacts the conductive portions ASDa and ASDb. Due to the offset region OS formed by the Vo, the effective length Leff of the channel CH can be reduced. The reduction in the effective length Leff of the channel CH can cause the threshold voltage Vth of the transistor to shift negatively (−). In other words, during the heating process, oxygen vacancies (Vo) from the conductive parts (ASDa and ASDb) can spread into the channel (CH) of the transistor. This can create an unwanted offset region (OS) in the channel (e.g., making the channel effectively shorter). This shortening of the channel can then cause the transistor's turn-on voltage (e.g., threshold voltage, Vth) to undesirably shift in a negative direction.

However, as shown in part (b) of FIG. 7, when the region where the dual doping portions RDa and RDb are to be formed is doped with a combination of boron (B) and fluorine (F), the phenomenon in which the threshold voltage Vth of the transistor shifts negatively (−) can be suppressed.

Specifically, when the region where the dual doping portions RDa and RDb are to be formed is doped with a combination of boron (B) and fluorine (F), more fluorine (F) can be present in the dual doping portion (RDa, RDb) compared to the conductive portions ASDa and ASDb of part (a) of FIG. 7.

Fluorine (F) present in the dual doping portions RDa and RDb can be bonded to the Vo while passivating Vo (oxygen vacancy) through the subsequent heat treatment process. For example, fluorine (F) can enter Vo to form a fluorine—Vo bond (Fo). Accordingly, according to an embodiment of the present disclosure, it is possible to reduce the content of Vo in the dual doping portions RDa and RDb, and suppress the occurrence of an offset region OS.

In addition, fluorine (F) can be bonded to a metal (M) through a subsequent heat treatment process to form a fluorine-metal bond (F—M) and the fluorine-metal bond (F—M) can function as an electron acceptor.

Accordingly, the fluorine-metal bond (F—M) can attract and capture electrons as carriers, thereby reducing the carrier concentration of the dual doping portions RDa and RDb, and adjusting the resistance of the dual doping portions RDa and RDb to be higher than the resistance of the first conductive portions ASD1a and ASD1b.

As such, according to the present disclosure, by providing the dual doping portions RDa and RDb, it is possible to suppress the phenomenon in which the threshold voltage Vth of the transistor shifts negatively (−), the occurrence of an offset portion and thus the reduction of the effective length Leff of the channel CH1. Accordingly, according to the present disclosure, it is possible to maximize the effective length Leff of the channel CH1. In other words, the dual doping portions (RDa and RDb) can help prevent the transistor's threshold voltage (Vth) from shifting negatively, suppress the formation of undesired offset portions, and avoid a reduction in the channel's effective length (Leff). As a result, the effective length of the channel (CH1) can be maximized and the transistor can have a more stable operation. For example, Leff in part (b) of FIG. 7 is longer than Leff in part (a) of FIG. 7.

In addition, by controlling the concentration of fluorine (F) in the dual doping portions RDa and RDb within an appropriate range, a margin for the heat treatment temperature of the subsequent heat treatment process can be increased. For example, with respect to the appropriate concentration of fluorine (F), the boron doping concentration to the fluorine doping concentration can be from 1:0.15 to 1:0.35 (e.g., 1:0.25) and the fluorine doping concentration in the dual doping portions RDa and RDb can be greater than 0 at % (atomic weight %) and less than 5 to 10 at % with respect to the total atomic weight of the dual doping portions RDa and RDb.

Such dual doping portions RDa and RDb can be applied to a switching transistor having a relatively long gate electrode, but embodiments of the present disclosure are not necessarily limited thereto. However, for convenience of illustration, the following description will be provided as an example where the switching transistor includes dual doping portions RDa and RDb, and the driving transistor DT does not include dual doping portions RDa and RDb.

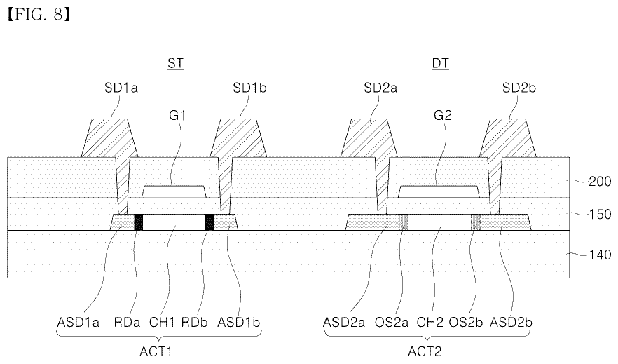

FIG. 8 illustrates comparison between the driving transistor applicable to the display device and the switching transistor according to an embodiment of the present disclosure.

As shown in FIG. 8, the display device of the present disclosure can include the driving transistor DT along with the switching transistor ST described above.

The switching transistor ST can be disposed on the substrate and can include a first gate electrode G1, a first source electrode SD1a, a first drain electrode SD1b, and a first active layer ACT1. The first active layer ACT1 can include a first channel portion CH1, first conductive portions ASD1a and ASD1b, and dual doping portions RDa and RDb. The switching transistor ST is the same as the switching transistor ST with reference to FIGS. 3 to 7 and thus the detailed description thereof will be omitted.

The driving transistor DT can be spaced apart from the switching transistor ST on the substrate. For example, as shown in FIG. 8, the driving transistor DT can be spaced apart from the switching transistor ST in the horizontal direction in which the buffer layer 140 extends on the buffer layer 140. The driving transistor DT can include a second gate electrode G2, a second source electrode SD2a, a second drain electrode SD2b, and a second active layer ACT2. Also, the driving transistor DT and the switching transistor ST can be on a same layer, or different layers.

The second gate electrode G2 of the driving transistor DT can be connected to the first node shown in part (a)_FIG. 2, and one of the second source electrode SD2a and the second drain electrode SD2b can receive a high potential driving voltage EVDD and the other thereof can be electrically connected to the light emitting element OLED. Accordingly, the driving transistor DT can generate a driving current flowing in the light emitting element OLED in response to the voltage applied to the second gate electrode G2.

The second gate electrode G2 can include a conductive material, for example, a metal such as aluminum (Al), chromium (Cr), copper (Cu), titanium (Ti), molybdenum (Mo), or tungsten (W).

The second active layer ACT2 can include an oxide semiconductor. For example, the oxide semiconductor material contained in the second active layer ACT2 can include at least one of an IZO (InZnO)-based, an IGO (InGaO)-based, an ITO (InSnO)-based, an IGZO (InGaZnO)-based, an IGZTO (InGaZnSnO)-based, a GZTO (GaZnSnO)-based, a GZO (GaZnO)-based, an ITZO (InSnZnO)-based, or a FIZO (FeInZnO)-based oxide semiconductor material.

The second active layer ACT2 of the driving transistor DT can include a second channel portion CH2, second conductive portions ASD2a and ASD2b, or second offset portions OS2a and OS2b.

The second channel portion CH2 can be positioned at a part of the second active layer ACT2 that overlaps the second gate electrode G2 and can be a region in which the first dopant is not doped. The second channel portion CH2 can form a channel through which carriers can move within the second active layer ACT2 depending on a voltage applied to the second gate electrode G2 and can generate a driving current.

The second conductive portions ASD2a and ASD2b can be positioned at both sides of the second channel portion CH2 and the second source electrode SD2a and the second drain electrode SD2b can contact the second conductive portions ASD2a and ASD2b.

The second conductive portions ASD2a and ASD2b can be formed by doping with the first dopant to allow the second active layer ACT2 to become conductive, can have a higher carrier concentration than the second channel portion CH2, and can have higher electrical conductivity and lower resistance than the second channel portion CH2. One of the second conductive portions ASD2a and ASD2b can correspond to the second source region ASD2a and the other can correspond to the second drain region ASD2b.

The second source electrode SD2a and the second drain electrode SD2b can be electrically connected to the second conductive portions ASD2a and ASD2b, respectively. The second source electrode SD2a can contact the second source region ASD2a and the second drain electrode SD2b can contact the second drain region ASD2b.

The second source electrode SD2a and the second drain electrode SD2b can be disposed on the interlayer insulating film 200 and can penetrate the interlayer insulating film 200 and the gate insulating film 150, and thus contact the second source region ASD2a and the second drain region ASD2b, respectively.

The second offset portions OS2a and OS2b can be positioned between the second channel portion CH2 and the second conductive portions ASD2a and ASD2b, but can overlap the end of the second gate electrode G2.

Specifically, the first region OS2a of the second offset portion OS2a or OS2b can be positioned between the second channel portion CH2 and the second source region ASD2a, and the other second region OS2b thereof can be positioned between the second channel portion CH2 and the second drain region ASD2b.

The second offset portions OS2a and OS2b can be doped with the first dopant at a lower concentration than the second conductive portions ASD2a and ASD2b, and the resistance can also be gradually changed as the carrier concentration gradually changes. For example, the second offset portions OS2a and OS2b can have a gradually increasing carrier concentration and a gradually decreasing resistance from the second channel portion CH2 to the second conductive portions ASD2a and ASD2b.

Since the second active layer ACT2 does not include dual doping portions RDa and RDb doped with the first and second dopants, the second offset portions OS2a and OS2b can directly contact the second conductive portions ASD2a and ASD2b.

Since the driving transistor DT includes a second channel portion CH2 longer than the first channel portion CH1 (e.g., length of CH2 >length of CH1), it can be driven stably even though it has second offset portions OS2a and OS2b, as shown in FIG. 8.

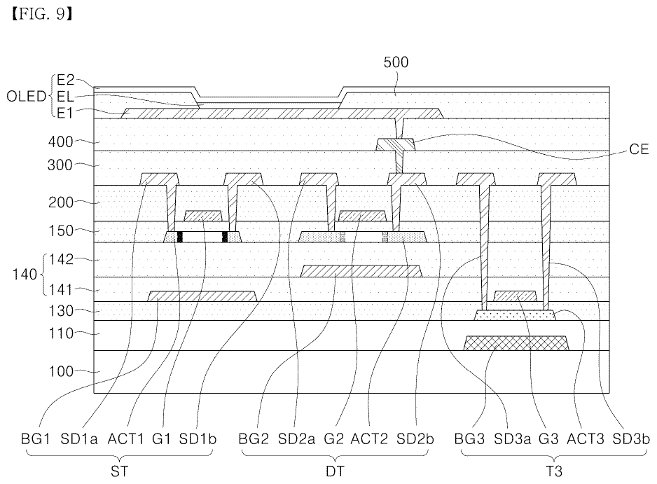

FIG. 9 illustrates an example in which the switching transistor and the driving transistor are applied to the display device according to an embodiment of the present disclosure.

The display device shown in FIG. 9 illustrates an example in which a third transistor T3 including a semiconductor containing low temperature polysilicon LTPS is provided in the switching transistor ST and the driving transistor DT. The third transistor T3 can be omitted in some situations.

FIG. 9 illustrates a configuration in which the driving transistor DT is electrically connected to the light emitting element OLED, but the present disclosure is not necessarily limited thereto. For example, the switching transistor ST can be electrically connected to the light emitting element OLED. For convenience of illustration, FIG. 9 illustrates a configuration in which the driving transistor DT is electrically connected to the light emitting element OLED as an example.

As shown in FIG. 9, the display device according to an embodiment of the present disclosure can include a substrate 100, a first insulating film 110, a second insulating film 130, a buffer layer 140, a gate insulating film 150, an interlayer insulating film 200, a first planarizing film 300, a second planarizing film 400, a bank insulating film 500, a light emitting element OLED, a switching transistor ST, a driving transistor DT, a third transistor T3, a first metal layer BG1, a second metal layer BG2, and a third metal layer BG3.

Since the buffer layer 140, the switching transistor ST, the driving transistor DT, the gate insulating film 150, and the interlayer insulating film 200 have been described with reference to FIG. 9, these components will be described briefly and other characteristics will be mainly described.

The substrate 100 can be formed of a flexible plastic material and thus can be flexible, and can also include a thin glass material having flexibility. The substrate 100 can be disposed in the active area AA and the non-active area NA of the display panel 10.

The substrate 100 can have a multilayer structure including an insulating material. For example, the substrate 100 can include a polymer material such as polyimide (PI) and an insulating material. A third metal layer BG3 disposed below the third transistor T3 can be provided on the substrate.

The third metal layer BG3 can function as a light-shielding pattern BSM that blocks external light entering the third transistor T3. In addition, in some situations, the third source electrode SD3a and the third drain electrode SD3b of the third transistor T3 can be electrically connected to one of the third source electrode SD3a and the third drain electrode SD3b of the third transistor T3, or can be connected to the third gate electrode G3 of the third transistor T3. Alternatively, the third metal layer BG3 can be connected to a constant voltage source.

The first insulating film 110 can be disposed on the active area AA and the non-active area NA on the substrate 100 such that it covers the third metal layer BG3. The first insulating film 110 can be disposed on the substrate 100 to protect structures on the substrate 100 that are vulnerable to moisture penetration through the substrate 100 and to flatten the surface of the substrate 100.

A third transistor T3 can be disposed on the first insulating film 110. The third transistor T3 can include a third gate electrode G3, a third active layer ACT3, a third source electrode SD3a, and a third drain electrode SD3b.

The third gate electrode G3 can be disposed on the second insulating film 130, can include a metal material, and can be controlled to form a channel in the third active layer ACT3 in response to an applied voltage.

The third active layer ACT3 can be disposed on the first insulating film 110, can include a semiconductor containing low temperature polysilicon LTPS, and can form a channel therein in response to a voltage applied to the third gate electrode G3.

The third source electrode SD3a and the third drain electrode SD3b can be disposed on the interlayer insulating film 200, can penetrate from the interlayer insulating film 200 to the second insulating film 130, and contact the third active layer ACT3.

The second insulating film 130 can be disposed on the first insulating film 110 to completely cover the active area AA and the third active layer ACT3 of the substrate 100. The second insulating film 130 can include an insulating material.

Each of the first and second insulating films 110 and 130 can be formed as a single layer of an inorganic film or can be formed as a multilayer structure of a plurality of inorganic films. For example, the first and second insulating films 110 and 130 can include at least one inorganic film of a silicon oxide (SiOx) film, a silicon nitride (SiNx) film, or a silicon oxynitride (SiOxNy) film.

A first metal layer BG1 and a third gate electrode G3 disposed at the bottom of the switching transistor ST can be disposed on the second insulating film 130. Also, the first metal layer BG1 can contact the first gate electrode G1 of the switching transistor ST and can function as a bottom gate electrode of the switching transistor ST.

The buffer layer 140 can be provided on the second insulating film 130 while covering the first metal layer BG1 and the third gate electrode G3. The buffer layer 140 can completely cover the active area AA of the substrate 100 and can include an insulating material. For example, the buffer layer 140 can include an inorganic insulating material such as silicon oxide (SiOx) or silicon nitride (SiNx), and can include a multilayer structure including the same material or different materials.

The buffer layer 140 can include, for example, a structure in which a first buffer layer 141 and a second buffer layer 142 are laminated. The first buffer layer 141 can include silicon nitride (SiNx) and the second buffer layer 142 can include silicon oxide (SiOx). The hydrogen concentration of the first buffer layer 141 can be higher than that of the second buffer layer 142.

A second metal layer BG2 can be disposed below the driving transistor DT between the first buffer layer 141 and the second buffer layer 142. Also, the second metal layer BG2 can contact the second gate electrode G2 of the driving transistor DT and can function as a bottom gate electrode of the driving transistor DT.

Alternatively, the second metal layer BG2 can contact one of the second source electrode SD2a and the second drain electrode SD2b. In this situation, the second metal layer BG2 can further stabilize the grayscale expression of the light emitting element OLED controlled by the driving transistor DT.

The switching transistor ST and the driving transistor DT can be disposed on the buffer layer 140. As shown in FIG. 9, when the switching transistor ST and the driving transistor DT are disposed on the same buffer layer 140, the process can be simplified (e.g., the number of manufacturing steps can be reduced), production energy can be reduced, greenhouse gas emissions that can be generated due to the manufacturing process can be reduced and thus ESG (environmental/social/governance) goals can be realized.

The switching transistor ST can include a first gate electrode G1, a first active layer ACT1, a first source electrode SD1a, and a first drain electrode SD1b, as shown in FIGS. 3 and 4. The first active layer ACT1 can include a first channel portion CH1, first conductive portions ASD1a and ASD1b, and dual doping portions RDa and RDb.

The driving transistor DT can include a second gate electrode G2, a second active layer ACT2, a second source electrode SD2a, and a second drain electrode SD2b, as shown in FIG. 8. The second active layer ACT2 can include a second channel portion CH2, second conductive portions ASD2a and ASD2b, and second offset portions OS2a and OS2b, as shown in FIG. 8.

The gate insulating film 150 can insulate the first gate electrode G1 from the first active layer ACT1 in the switching transistor ST, and the second gate electrode G2 from the second active layer ACT2 in the driving transistor DT.

The interlayer insulating film 200 can be disposed on the gate insulating film 150 to cover the first gate electrode G1 of the switching transistor ST and the second gate electrode G2 of the driving transistor DT. The first source electrode SD1a and the first drain electrode SD1b of the switching transistor ST can be disposed on the interlayer insulating film 200, and the second source electrode SD2a and the second drain electrode SD2b of the driving transistor DT can be disposed.

The first source electrode SD1a and the first drain electrode SD1b of the switching transistor ST can penetrate the interlayer insulating film 200 and the gate insulating film 150 and contact the first conductive portions ASD1a and ASD1b of the switching transistor ST, and the second source electrode SD2a and the second drain electrode SD2b of the driving transistor DT can penetrate the interlayer insulating film 200 and the gate insulating film 150 and contact the second conductive portions ASD2a and ASD2b of the driving transistor DT.

The planarization films 300 and 400 can include an insulating material and can be disposed on the interlayer insulating film 200 to cover the switching transistor ST and the driving transistor DT. The planarization films 300 and 400 can remove the step caused by the transistor within the subpixel SP. The planarization film 300 can have a flat upper surface and can include a material having high fluidity. For example, the planarization film 300 can include an organic insulating material.

The planarization films 300 and 400 can include a first planarization film 300 and a second planarization film 400. The first planarization film 300 and the second planarization film 400 can be sequentially laminated on the interlayer insulating film 200 to cover the first source electrode SD1a and the first drain electrode SD1b of the switching transistor ST and the second source electrode SD2a and the second drain electrode SD2b of the driving transistor.

The first planarization film 300 and the second planarization film 400 can remove a step caused by the driving circuit such as the switching transistor ST or the driving transistor DT. The upper surfaces of the first planarization film 300 and the second planarization film 400 can be flat, and for example, the upper surface of each of the first planarization film 300 and the second planarization film 400 facing the light emitting element OLED can be flat.

To this end, the first planarization film 300 and the second planarization film 400 can include a material having high fluidity. For example, the first planarization film 300 and the second planarization film 400 can include an organic insulating material. The second planarization film 400 can include a different material from the first planarization film 300. Accordingly, the step caused by the driving circuits can be effectively eliminated.

An intermediate electrode CE can be disposed between the first planarization film 300 and the second planarization film 400. The intermediate electrode CE can include a conductive material. For example, the intermediate electrode CE can include a metal such as aluminum (Al), chromium (Cr), copper (Cu), titanium (Ti), molybdenum (Mo), or tungsten (W).

For example, the intermediate electrode CE can electrically connect the driving transistor DT to the light emitting element OLED. For example, as shown in FIG. 9, the intermediate electrode CE can penetrate the first planarization film 300 and the second planarization film 400 and electrically connect the second drain electrode SD2b of the driving transistor DT to the first electrode E1 of the light emitting element OLED.

In addition, an intermediate electrode can be further provided between the first planarization film 300 and the second planarization film 400 to electrically connect the switching transistor ST to the driving transistor DT, or to electrically connect the switching transistor ST to another circuit element.

FIG. 9 illustrates an example in which the second drain electrode SD2b of the driving transistor DT contacts the first electrode E1 of the light emitting element OLED through the intermediate electrode CE, but the present disclosure is not necessarily limited thereto, and in some situations, the switching transistor ST, which is the intermediate electrode CE, can be electrically connected to the light emitting element OLED, unlike the configuration of FIG. 9.

A bank insulating film 500 can be disposed on the second planarization film 400 and the bank insulating film 500 can define a light emitting area in each subpixel SP. The bank insulating film 500 can include an insulating material. For example, the bank insulating film 500 can include an organic insulating material. The bank insulating film 500 can include a different material from the first planarization film 300 and the second planarization film 400. The bank insulating film 500 can cover an edge of the first electrode E1. The light emitting layer EL and the second electrode E2 can be laminated on a part of the first electrode E1 exposed by the bank insulating film 500.

A light emitting element OLED can be disposed in the light emitting region and the light emitting element OLED can include a first electrode E1, a light emitting layer EL, and a second electrode E2.

The first electrode E1 can, for example, function as an anode and can include a conductive material. The first electrode E1 can have a high reflectivity. For example, the first electrode E1 can include a metal such as aluminum (Al) or silver (Ag). The first electrode E1 can have a multilayer structure. For example, the first electrode E1 can have a structure in which a reflective electrode formed of a metal is disposed between transparent electrodes formed of a transparent conductive material such as ITO or IZO.

The light emitting layer EL can generate light having a brightness corresponding to a voltage difference between the first electrode E1 and the second electrode E2. For example, the light emitting layer EL can include an emission material layer EML including an emission material. The emission material can include an organic material, an inorganic material, or a hybrid material. For example, the light emitting layer EL can include an emission material layer containing an organic material.

The light emitting layer EL can include at least one of a first light emitting common layer disposed between the first electrode E1 and a second light emitting common layer disposed between the second electrode E2. Each of the first light emitting common layer and the second light emitting common layer can include at least one of a hole injection layer HIL, a hole transport layer HTL, an electron transport layer ETL, or an electron injection layer EIL.

The light emitting layer EL can emit red (R), green (G), blue (B), or white (W) light.

The second electrode E2 functions as a cathode and can, for example, include a conductive material. The second electrode E2 can include a different material from the first electrode E1. For example, the second electrode E2 can be a transparent electrode containing a transparent conductive material such as ITO or IZO. The second electrode E2 can have a higher transmittance than the first electrode E1.

Accordingly, in the display device according to the embodiment of the present disclosure, light generated by the light emitting layer EL can be emitted through the second electrode E2.

FIG. 9 illustrates an example in which a switching transistor ST includes dual doping portions RDa and RDb and a driving transistor DT that does not include dual doping portions RDa and RDb, but the present disclosure is not necessarily limited thereto. In some situations, the driving transistor DT can also include dual doping portions RDa and RDb.

In addition, in some situations, the transistor provided in the GIP driving circuit disposed in the non-active area (NA) of the panel can also include dual doping portions RDa and RDb.

Therefore, according to the present disclosure, it is possible to suppress the phenomenon in which the threshold voltage Vth of the transistor shifts negatively by providing dual doping portions RDa and RDb doped with a combination of a first dopant and a second dopant between the conductive portion doped with the first dopant and a channel region in a transistor.

In addition, according to the present disclosure, it is possible to suppress the occurrence of an offset portion and reduce the content of Vo in the dual doping portions RDa and RDb because the fluorine (F) doped in the dual doping portions RDa and RDb is bonded to the Vo (oxygen vacancy) to form a fluorine—Vo bond (Fo).

In addition, according to the present disclosure, it is possible to increase the resistance of the dual doping portions RDa and RDb through a fluorine-metal bond (F—M) formed between fluorine and a metal (M) doped in the dual doping portions RDa and RDb, thereby suppressing the phenomenon in which the threshold voltage Vth of the transistor shifts negatively (−).

According to the present disclosure, it is possible to improve the power of the transistor and reduce the power consumption of the display device, thereby realizing ESG goals.

According to the present disclosure, it is possible to improve the power of the transistor and reduce the power consumption of the display device, thereby realizing ESG goals.

As apparent from the foregoing, according to the present disclosure, it is possible to suppress the phenomenon in which the threshold voltage Vth of the transistor shifts negatively by providing dual doping portions RDa and RDb doped with a combination of a first dopant and a second dopant between a conductive portion doped with the first dopant and a channel region in the transistor.

In addition, according to the present disclosure, it is possible to suppress the occurrence of an offset portion and reduce the content of Vo in the dual doping portions RDa and RDb because the fluorine (F) doped in the dual doping portions RDa and RDb is bonded to the Vo (oxygen vacancy) to form a fluorine-Vo bond (Fo).

In addition, according to the present disclosure, it is possible to increase the resistance of the dual doping portions RDa and RDb through a fluorine-metal bond (F—M) formed between fluorine and a metal (M) doped in the dual doping portions RDa and RDb, thereby suppressing the phenomenon in which the threshold voltage Vth of the transistor shifts negatively (−).

According to the present disclosure, it is possible to improve the power of the transistor and reduce the power consumption of the display device, thereby realizing ESG goals.

According to the present disclosure, it is possible to improve the power of the transistor and reduce the power consumption of the display device, thereby realizing ESG goals.

It will be apparent to those skilled in the art that various modifications and variations can be made in the present disclosure without departing from the spirit or scope of the disclosure. Thus, it is intended that the present disclosure covers the modifications and variations of the present disclosure provided they fall within the scope of the appended claims and their equivalents.

What is claimed is:

1. A transistor comprising:
a first gate electrode;
a first active layer overlapping with the first gate electrode; and
a first source electrode and a first drain electrode contacting the first active layer,
wherein the first active layer comprises:
a first channel portion overlapping with the first gate electrode;
a first conductive portion positioned at opposite sides of the first channel portion, the first conductive portion being doped with a first dopant and contacting the first source electrode and the first drain electrode; and
a dual doping portion positioned between the first conductive portion and the first channel portion, the dual doping portion being doped with the first dopant and a second dopant different from the first dopant.

2. The transistor according to claim 1, wherein a resistance of the dual doping portion is higher than a resistance of the first conductive portion, and
wherein the resistance of the dual doping portion is lower than a resistance of the first channel portion.

3. The transistor according to claim 1, wherein a carrier concentration in the dual doping portion is lower than a carrier concentration in the first conductive portion, and
wherein the carrier concentration in the dual doping portion is higher than a carrier concentration in the first channel portion.

4. The transistor according to claim 1, wherein a width of the dual doping portion is smaller than a width of the first conductive portion.

5. The transistor according to claim 1, wherein a concentration of the first dopant in the dual doping portion is different than a concentration of the second dopant in the dual doping portion.

6. The transistor according to claim 5, wherein the first dopant comprises boron (B), and the second dopant comprises fluorine (F).

7. The transistor according to claim 6, wherein a concentration of the fluorine (F) in the dual doping portion is less than a concentration of the boron (B) in the dual doping portion.

8. The transistor according to claim 1, further comprising:
a first offset portion positioned between the dual doping portion and the first channel portion and having a carrier concentration increasing in a direction from the first channel portion to the dual doping portion.

9. The transistor according to claim 8, wherein a width of the dual doping portion is greater than a width of the first offset portion, and the width of the dual doping portion is smaller than a width of the first conductive portion.

10. The transistor according to claim 1, wherein the first active layer comprises an oxide semiconductor.

11. A display device comprising:
a switching transistor disposed on a substrate, the switching transistor including a first gate electrode, a first source electrode, a first drain electrode, and a first active layer; and
a driving transistor disposed on the substrate and spaced apart from the switching transistor, the driving transistor including a second gate electrode, a second source electrode, a second drain electrode, and a second active layer,
wherein the first active layer comprises:
a first channel portion overlapping with the first gate electrode;
a first conductive portion positioned at opposite sides of the first channel portion, the first conductive portion being doped with a first dopant and contacting the first source electrode and the first drain electrode; and
a dual doping portion positioned between the first conductive portion and the first channel portion, the dual doping portion being doped with a combination of the first dopant and a second dopant different from the first dopant, and
wherein the second active layer comprises:
a second channel portion overlapping with the second gate electrode;
a second conductive portion positioned at opposite sides of the second channel portion and doped with the first dopant, the second conductive portion contacting the second source electrode and the second drain electrode; and
a second active layer offset portion positioned between the second channel portion and the second conductive portion, the second active layer offset portion being doped with the first dopant and having a resistance that changes based on a distance away from second channel portion.

12. The display device according to claim 11, wherein the second active layer does not include a dual doping portion doped with the first and second dopants together.

13. The display device according to claim 11, wherein a resistance of the dual doping portion is higher than a resistance of the first conductive portion, and
wherein the resistance of the dual doping portion is lower than a resistance of the first channel portion.

14. The display device according to claim 11, wherein a carrier concentration in the dual doping portion is lower than a carrier concentration in the first conductive portion, and
wherein the carrier concentration in the dual doping portion is higher than a carrier concentration in the first channel portion.

15. The display device according to claim 11, wherein a width of the dual doping portion is smaller than a width of the first conductive portion.

16. The display device according to claim 11, wherein a concentration of the first dopant in the dual doping portion is different than a concentration of the second dopant in the dual doping portion.

17. The display device according to claim 16, wherein the first dopant comprises boron (B), and the second dopant comprises fluorine (F).

18. The display device according to claim 17, wherein a concentration of the fluorine (F) in the dual doping portion is less than a concentration of the boron (B) in the dual doping portion.

19. The display device according to claim 11, further comprising:
a first active layer offset portion positioned between the dual doping portion and the first channel portion and having a carrier concentration increasing in a direction from the first channel portion to the dual doping portion.

20. The display device according to claim 11, wherein the first and second active layers comprise an oxide semiconductor.

21. A transistor comprising:
a first active layer including a first conductive portion, a second conductive portion, a first channel portion, a first dual doping portion between the first conductive portion and the first channel portion and second dual doping portion between the first channel portion and the second conductive portion; and
a first gate electrode overlapping with a portion of the first active layer,
wherein the first dual doping portion includes a first dopant and a second dopant,
wherein the second dual doping portion includes the first dopant and the second dopant,
wherein a length of the first dual doping portion is less than a length of the first conductive portion and a length of the first channel portion,
wherein a length of the second dual doping portion is less than a length of the second conductive portion and the length of the first channel portion, and
wherein the second dopant is absent from the first conductive portion, the second conductive portion and the first channel portion.

22. The transistor according to claim 21, wherein the first dopant includes boron (B), and the second dopant includes fluorine (F).

23. The transistor according to claim 21, wherein a doping concentration of the second dopant to the first dopant in both of the first and second dual doping portions is 1:0.15 to 1:0.35.

24. The transistor according to claim 21, wherein a doping concentration of the second dopant in both of the first and second dual doping portions is greater than 0 atomic weight percent and less than 5 to 10 atomic weight percent with respect to a total atomic weight in the first and second dual doping portions.
